(19) United States
(12) Patent Application Publication
(10) Pub. No.: US 2013/0060497 A1
(43) Pub. Date: Mar. 7, 2013

(54) BATTERY STATE MONITORING DEVICE

(71) Applicant: Seiji Bito, Hamamatsu-shi (JP)

(72) Inventor: Seiji Bito, Hamamatsu-shi (JP)

(73) Assignee: SUZUKI MOTOR CORPORATION, Shizuoka-ken (JP)

(21) Appl. No.: 13/409,622

(22) Filed: Mar. 1, 2012

(30) Foreign Application Priority Data
Mar. 23, 2011 (JP) 2011-064000

(51) Int. Cl. G01R 31/36

(52) U.S. Cl. 702/63

(57) ABSTRACT

A battery state monitoring device includes a battery pack including at least one battery cell, and a measuring circuit that measures a state of the battery cell, the measuring circuit including temperature measuring means for measuring a temperature of the battery cell, current measuring means for measuring a current flowing through the battery cell, and voltage measuring means for measuring a voltage of the battery cell, and including a calculation circuit in parallel, wherein the battery state monitoring device calculates a predetermined voltage corresponding to a predetermined state of charge of the battery cell, based on the temperature and the current of the battery cell, using a predetermined operational expression including a temperature quadratic exponential function and a temperature linear function, and compares the voltage of the battery cell with the predetermined voltage calculated using the operational expression to determine the predetermined state of charge of the battery cell.

### CROSS-REFERENCE TO RELATED APPLICATIONS

The present application claims priority from Japanese Patent Application No. 2011-064000 filed Mar. 23, 2011, the disclosure of which is hereby incorporated herein by reference.

### BACKGROUND OF THE INVENTION

The present invention relates to a battery state monitoring device, and more particularly, relates to a battery state monitoring device that monitors a state of a battery cell in a battery pack as a drive energy source, and estimates a state of charge of the battery cell.

Motor vehicles such as electric vehicles (EV), hybrid vehicles (HEV), or plug-in hybrid vehicles (PHEV) including a battery pack as a drive energy source are desired to measure a state of a battery cell and correctly calculate a state of charge (SOC).

Generally, a state of charge of a battery correlates with an open circuit voltage (OCV), and the state of charge can be estimated by calculating the open circuit voltage. There is a battery state monitoring device using a method for calculating a state of charge as an amount of change from an initial state of charge using current integration.

A conventional battery state monitoring device uses a method for estimating a convergence value of an open circuit voltage of a battery cell that changes in an open circuit, and estimating a state of charge using a correlation map between the state of charge and the open circuit voltage (JP 2005-43339 A).

However, with the method in JP 2005-43339 A, the convergence value of the open circuit voltage changes when the battery cell deteriorates, thereby increasing estimation errors of the state of charge. This problem is particularly serious for an aqueous battery cell such as a lead battery or a nickel hydrogen battery.

### SUMMARY OF THE INVENTION

The present invention has an object to calculate a predetermined state of charge as a point from a closed circuit voltage (CCV) rather than an open circuit voltage, and accurately calculate a state of charge at the point with a small change even if a battery cell deteriorates.

The present invention provides a battery state monitoring device including: a battery pack including at least one battery cell; and a measuring circuit that measures a state of the battery cell, the measuring circuit including temperature measuring means for measuring a temperature of the battery cell, current measuring means for measuring a current flowing through the battery cell, and voltage measuring means for measuring a voltage of the battery cell, and including a calculation circuit in parallel, wherein the battery state monitoring device calculates a predetermined voltage corresponding to a predetermined state of charge of the battery cell, based on the temperature of the battery cell measured by the temperature measuring means and the current of the battery cell measured by the current measuring means, using a predetermined operational expression including a temperature quadratic exponential function and a temperature linear function, and wherein the battery state monitoring device compares the voltage of the battery cell measured by the voltage measuring means with the predetermined voltage calculated using the operational expression to determine the predetermined state of charge of the battery cell.

The battery state monitoring device of the present invention can reduce determination errors due to deterioration of the battery cell as compared to a case of calculation of a state of charge from an open circuit voltage by estimation, thereby ensuring high accuracy. High accuracy can be particularly ensured in a room temperature range with a temperature of the battery cell of 0° C. or more.

### BRIEF DESCRIPTION OF THE DRAWINGS

FIG. 1 is a system configuration diagram of a battery state monitoring device (embodiment);

FIG. 2 is a flowchart of calculation of a state of charge (embodiment); and

FIG. 3 shows a determination result of the state of charge with respect to a temperature of a battery cell (embodiment).

### DETAILED DESCRIPTION OF THE INVENTION

Now, an embodiment of the present invention will be described with reference to the drawings.

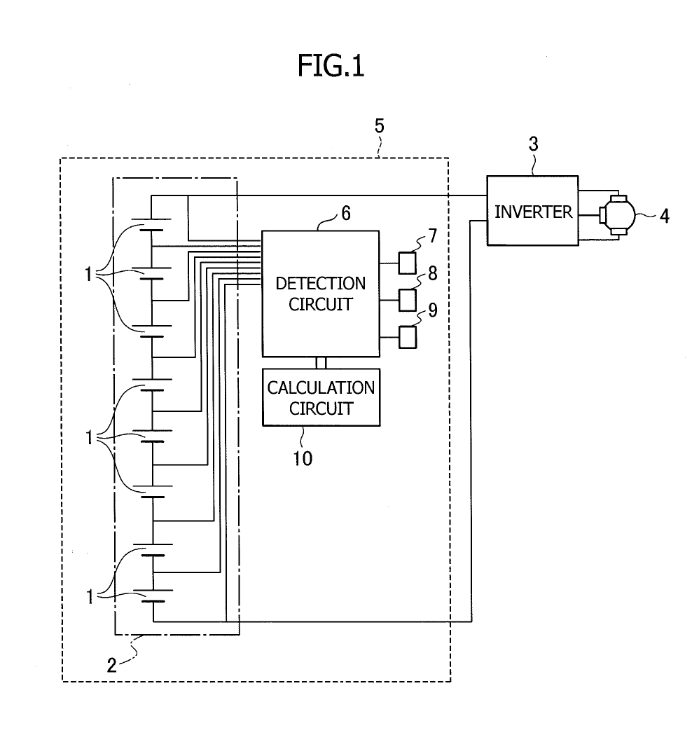

FIGS. 1 to 3 show the embodiment of the present invention. In FIG. 1, reference numeral 1 denotes a battery cell, 2; a battery pack including at least one battery cell 1, 3; an inverter, 4; a drive motor for a motor vehicle such as an electric vehicle, a hybrid vehicle, or a plug-in hybrid vehicle. The battery pack 2 is connected via the inverter 3 to the drive motor 4. The drive motor 4 generates a drive force from power supplied from the battery pack 2 via the inverter 3 during driving, drives drive wheels of the motor vehicle using the generated drive force, generates electric energy using the drive force from the drive wheels during regeneration, and supplies the generated electric energy via the inverter 3 to the battery pack 2 for charging.

The battery pack 2 needs to correctly understand a state of charge (SOC) of the battery cell 1 to properly perform charge and discharge by driving and regeneration of the drive motor 4. Thus, in the battery pack 2, a battery state monitoring device 5 monitors the state of charge of the battery cell 1. The battery state monitoring device 5 includes a measuring circuit 6 that measures a state of each battery cell 1 in the battery pack 2 including one or more battery cells 1. The measuring circuit 6 includes temperature measuring means 7 for measuring a temperature T of the battery cell 1, current measuring means 8 for measuring a current i flowing through the battery cell 1, and voltage measuring means 9 for measuring a voltage V of the battery cell 1, and also includes a calculation circuit 10 in parallel.

The battery state monitoring device 5 calculates, in the calculation circuit 10, a predetermined voltage (for example, 30 V) corresponding to a predetermined state of charge (for example, SOC 30%), based on the measured current i and temperature T of the battery cell 1, using a predetermined operational expression (Expression 1) including a temperature quadratic exponential function (Expression 2) and a temperature linear function (Expression 3) mentioned below, and compares the measured voltage V with the predetermined voltage (30 V) to determine the predetermined state of charge (SOC 30%) of the battery cell 1.

V30=f1(T)×i+f2(T) Expression 1

f1(T)=EXP(a*(LOG(T+273))̂2+b*LOG(T+273)+c). Expression 2

f2(T)=d*(T+273)+e Expression 3

where i is battery cell current (A) and T is battery cell temperature (° C.).

The battery pack 2 properly controls charge and discharge by driving and regeneration of the drive motor 4 based on a determination result of the predetermined state of charge (SOC 30%) of the battery cell 1. For example, the battery pack 2 controls driving of the drive motor 4 so that the battery cell 1 does not fall below the predetermined state of charge (SOC 30%) during discharge. Parameters a to e in Expressions 1 and 2 can be prepared based on experimental data, and an expression can be prepared for determining any state of charge other than 30% as a predetermined state of charge.

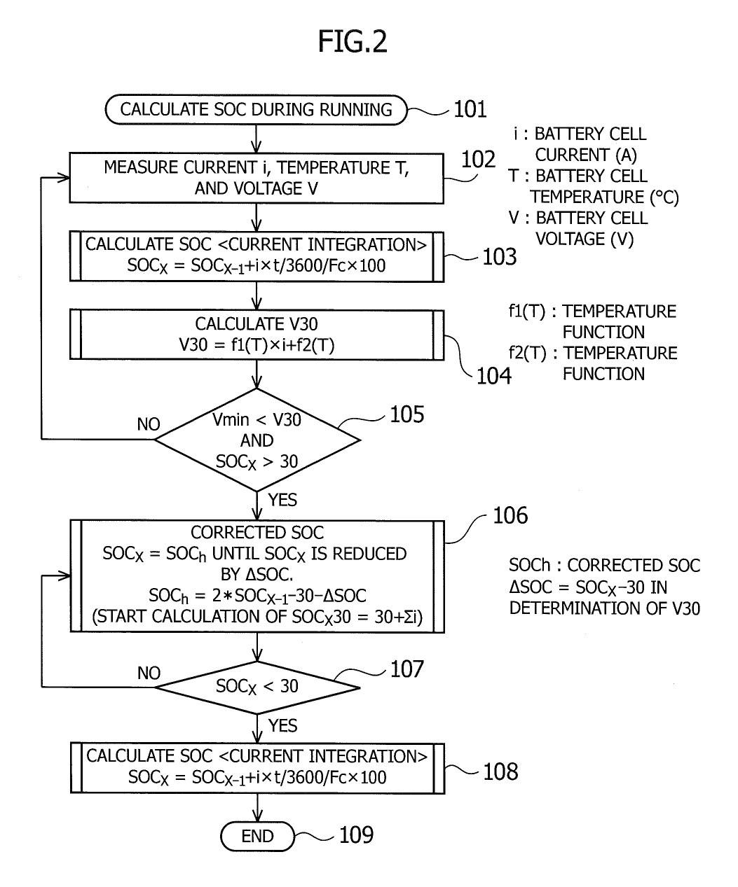

Next, an operation of the battery state monitoring device 5 will be described with reference to a flowchart in FIG. 2.

When a program for calculation of a state of charge (SOC) during running starts (101), the battery state monitoring device 5 measures the temperature T, the current i, and the voltage V of the battery cell 1 (102), and calculates a present state of charge (SOCX) from a current integration expression in Expression 4 below (103). For calculation of the state of charge (SOCX), a previous state of charge (SOCX−1) at completion stored in the calculation circuit 10 is used.

SOCX=SOCX−1+i×t/3600/Fc'100 Expression 4

where SOCX is present state of charge, SOCX−1 is previous state of charge, and Fc is battery cell capacity (Ah).

Then, the predetermined voltage (V30) is calculated from Expression 1 (104). A minimum value Vmin of the measured battery cell voltage V is compared with the predetermined voltage (V30), and it is determined whether the minimum value Vmin of the battery cell voltage V is less than the predetermined voltage (V30) and the present state of charge (SOCX) is greater than the predetermined state of charge (SOC 30%) (105).

When this determination is NO, the process returns to the measurement (102). When this determination is YES, the present state of charge (SOCX) is reduced to the predetermined state of charge (SOC 30%) by Expression 5 below and corrected to a corrected state of charge (SOCh) (106).

SOCX=SOCh=2×SOCX−1−30−ΔSOC Expression 5

where SOCh is corrected state of charge and ΔSOC is SOCX−30 in determination of V30.

It is determined whether the present state of charge (SOCX) corrected in the correction (106) is reduced to the predetermined state of charge (SOC 30%) or less (107).

When the present state of charge (SOCX) is not reduced to the predetermined state of charge (SOC 30%) or less, and the determination (107) is NO, the process returns to the correction (106). When the present state of charge (SOCX) is reduced to the predetermined state of charge (SOC 30%) or less, and the determination (107) is YES, the present state of charge (SOCX) is calculated from the current integration expression in Expression 4 (108), and the program is finished (109).

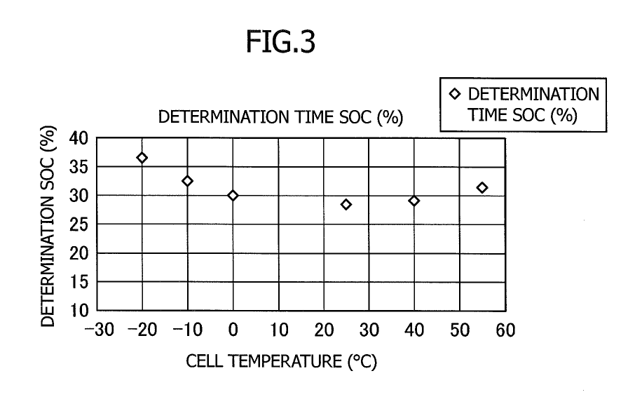

FIG. 3 shows a determination result of the state of charge with respect to the battery cell temperature when the predetermined state of charge (SOC 30%) is calculated by Expression 1. Since an impedance in the battery suddenly changes at a low battery cell temperature of 0° C. or less, determination of the predetermined voltage (V30) is desirably masked.

As such, the battery state monitoring device 5 calculates the predetermined voltage (30 V) corresponding to the predetermined state of charge (SOC 30%) of the battery cell 1, based on the temperature T of the battery cell 1 measured by the temperature measuring means 7 and the current i of the battery cell 1 measured by the current measuring means 8, using the predetermined operational expression (Expression 1) including the temperature quadratic exponential function (Expression 2) and the temperature linear function (Expression 3), and compares the voltage V of the battery cell 1 measured by the voltage measuring means 9 with the predetermined voltage (30V) calculated using the operational expression (Expression 1) to determine the predetermined state of charge (SOC 30%) of the battery cell 1.

Thus, the battery state monitoring device 5 can accurately calculate the state of charge (SOC) in a closed circuit, can reduce determination errors due to deterioration of the battery cell 1 as compared to a case of calculation of a state of charge from an open circuit voltage by estimation, thereby ensuring high accuracy in measuring of the state of charge (SOC). High accuracy can be particularly ensured in a room temperature range with a temperature of the battery cell 1 of 0° C. or more.

The battery state monitoring device 5 calculates the present state of charge (SOCX) of the battery cell 1 from the sum of the previous state of charge (SOCX−1) and the current integration (i×t/3600/Fc×100), corrects the present state of charge (SOCX) when the minimum value (Vmin) of the measured voltage of one or more battery cell 1 is less than the predetermined voltage (V30) calculated using the operational expression (Expression 1), and the calculated present state of charge (SOCX) is greater than the predetermined state of charge (SOC 30%), and updates the correction to the corrected state of charge (SOCh) calculated by subtracting a difference between the present state of charge (SOCX) and the predetermined state of charge (SOC 30%) from a value obtained by subtracting the predetermined state of charge (SOC 30%) from a multiple of the previous state of charge (SOCX−1).

Thus, the battery state monitoring device 5 can gently correct the state of charge (SOC) of the battery cell 1.

The present invention can ensure high accuracy in measuring of the state of charge of the battery cell, and can be applied to the field of stationary power supplies such as a power supply for a wind power generation buffer, or a domestic night power storage device besides measuring of the state of charge of the battery cell mounted in the motor vehicle.

What is claimed is:

1. A battery state monitoring device comprising:
a battery pack including at least one battery cell; and
a measuring circuit that measures a state of the battery cell,
the measuring circuit including temperature measuring means for measuring a temperature of the battery cell, current measuring means for measuring a current flowing through the battery cell, and voltage measuring means for measuring a voltage of the battery cell, and including a calculation circuit in parallel,
wherein the battery state monitoring device calculates a predetermined voltage corresponding to a predetermined state of charge of the battery cell, based on the temperature of the battery cell measured by the temperature measuring means and the current of the battery cell measured by the current measuring means, using a predetermined operational expression including a temperature quadratic exponential function and a temperature linear function, and
wherein the battery state monitoring device compares the voltage of the battery cell measured by the voltage measuring means with the predetermined voltage calculated using the operational expression to determine the predetermined state of charge of the battery cell.

2. The battery state monitoring device according to claim 1,
wherein the battery state monitoring device calculates a present state of charge of the battery cell from the sum of a previous state of charge and current integration, and
wherein the battery state monitoring device corrects the present state of charge when a minimum value of the measured voltage of at least one battery cell is less than the predetermined voltage calculated using the operational expression, and the calculated present state of charge is greater than the predetermined state of charge, and
wherein the battery state monitoring device updates the correction to a corrected state of charge calculated by subtracting a difference between the present state of charge and the predetermined state of charge from a value obtained by subtracting the predetermined state of charge from a multiple of the previous state of charge.
